(19) United States
(12) Patent Application Publication
(10) Pub. No.: US 2025/0149335 A1
(43) Pub. Date: May 8, 2025

(54) METHOD TO PATTERN A SEMICONDUCTOR SUBSTRATE USING A MULTILAYER PHOTORESIST FILM STACK

(71) Applicant: Tokyo Electron Limited, Tokyo (JP)

(72) Inventors: Kandabara Tapily, Albany, NY (US); Eric Chih-Fang Liu, Albany, NY (US); Lior Huli, Albany, NY (US)

(21) Appl. No.: 18/387,619

(22) Filed: Nov. 7, 2023

(51) Int. Cl. H01L 21/027; G03F 7/11; G03F 7/40; H01L 21/033

(52) U.S. Cl. CPC H01L 21/0274; G03F 7/11; G03F 7/40; H01L 21/0337

(57) ABSTRACT

Embodiments of methods are provided herein to form an extreme ultra-violet (EUV) photoresist pattern on a semiconductor substrate using a multilayer photoresist film stack. The disclosed embodiments begin by forming a multilayer photoresist film stack including a plurality of relatively thin photoresist film layers, each layer comprising a different photoresist material. After EUV exposure, the disclosed embodiments selectively develop the different photoresist layers in separate different development steps. In doing so, the process flows and methods disclosed herein increase the resist film thickness and improve development selectivity to avoid the photoresist damage and photoresist pattern collapse that often occurs during conventional EUV lithography processes.

### TECHNICAL FIELD

The present invention relates generally to patterning methods for semiconductor substrates and, in particular embodiments, to methods to increase photoresist film thickness while avoiding photoresist pattern collapse.

### BACKGROUND

Generally, a semiconductor device, such as an integrated circuit (IC) is fabricated by sequentially depositing and patterning layers of dielectric, conductive, and semiconductor materials over a semiconductor substrate to form a network of electronic components and interconnect elements (e.g., transistors, resistors, capacitors, metal lines, contacts, and vias) integrated in a monolithic structure. At each successive technology node, the minimum feature sizes are shrunk to reduce cost by roughly doubling the component packing density.

A common patterning method is to use a photolithography process to expose a coating of photoresist over the target layer to a pattern of actinic radiation and then transfer the relief pattern to the target layer or an underlying hard mask layer formed over the target layer. With this technique, the minimum feature size would be limited by the resolution of the optical system. Scaling of feature sizes for advanced technology nodes is driving lithography to improve resolution. For sub-10 nm technology nodes (for example, 7 nm and 5 nm nodes), 13.5 nm extreme ultraviolet (EUV) lithography is commonly used to pattern a photoresistive film with EUV radiation.

EUV lithography techniques offer significant advantages in patterning sub-10 nm features with its high optical resolution. However, one major engineering challenge for EUV lithography is that photoresists developed for conventional photolithography systems may not satisfy the cost and/or quality requirements for patterning sub-10 nm features. For example, chemically amplified resist (CAR) or similar polymer resists, which are commonly used in 193 nm lithography, are typically produced using liquid based spin-on techniques that consume a significant amount of complex metal cluster precursors, resulting in very high cost. CARs also tend to have low absorption coefficients at 13.5 nm, and thus, may suffer poor sensitivity. Further, the diffusion of photo-activated species in CARs may cause blurring and increase line-edge roughness (LER) in the subsequently formed pattern.

Metal-oxide photoresists are attracting attention for use in EUV lithography due to the high etch resistance/selectivity and photo reactivity to EUV of such resists. In a typical EUV lithography process, a wet or dry process may be used to deposit a metal-oxide photoresist film on at least one underlayer formed above a semiconductor substrate. The metal-oxide photoresist film can be patterned with EUV lithography to form a photoresist pattern on the underlayer(s) before an etch process is used to transfer the photoresist pattern to the underlayer(s). Although a wet or dry process may be utilized, a dry etch process (e.g., a plasma-based etch process) is typically used to transfer the metal-oxide photoresist pattern to the underlayer(s).

Challenges remain with patterning underlayers using metal-oxide photoresists and other photoresists typically utilized for EUV lithography. When relatively thin photoresist films (having a film thickness <15 nm) are used to form low aspect ratio photoresist patterns, the etch process used to transfer the photoresist pattern to the underlayer(s) may damage the photoresist pattern by significantly etching (or completely removing) portions of the thin photoresist film. In some cases, photoresist damage may be alleviated by depositing a substantially thicker photoresist film (having a film thickness >20 nm) on the underlayer(s) to form a higher aspect ratio photoresist pattern. However, patterning thick photoresist films has its own challenges, oftentimes resulting in photoresist line or pillar collapse.

Accordingly, a need remains for improved EUV photoresists and methods of forming such resists.

### SUMMARY

The present disclosure provides various embodiments of improved process flows and methods for processing a semiconductor substrate. More specifically, the present disclosure provides improved process flows and methods that utilize a multilayer photoresist film stack to form an extreme ultra-violet (EUV) photoresist pattern on a semiconductor substrate. The multilayer photoresist film stack disclosed herein includes a plurality of relatively thin photoresist film layers, each layer comprising a different photoresist material.

In the disclosed embodiments, a multilayer photoresist film stack is deposited on at least one underlayer formed above a semiconductor substrate and patterned using EUV lithography to form an EUV photoresist pattern on the underlayer(s). The multilayer photoresist film stack deposited on the underlayer(s) includes at least a first photoresist layer and a second photoresist layer formed above the first photoresist layer. The first and second photoresist layers are relatively thin photoresist films (having, e.g., a film thickness less than 15 nm) formed from different photoresist materials. A wide variety of photoresist materials may be used within the multilayer photoresist film stack, as discussed further below.

The improved processes and methods disclosed herein provide a multilayer photoresist film stack for use in EUV lithography. In the disclosed embodiments, the multilayer photoresist film stack is exposed to EUV radiation to convert portions of the first and second photoresist layers to reacted photoresist in a single exposure step. After EUV exposure, the multilayer photoresist film stack is exposed to at least two different development steps to selectively develop the first and second photoresist layers included within the multilayer photoresist film stack. Because the first and second photoresist layers are implemented with different photoresist materials, each photoresist layer is selectively developed, one at a time, to mitigate pattern collapse.

The improved processes and methods disclosed herein overcome the challenges typically faced when conventional EUV lithography are used to form a photoresist pattern on a semiconductor substrate. As noted above and described further below, a plurality of relatively thin, yet different, photoresist film layers are combined within a multilayer photoresist film stack to increase the overall resist film thickness. By combining different photoresist layers within a multilayer photoresist film stack, and using two different development steps to selectively develop the different photoresist layers, the processes and methods disclosed herein avoid the photoresist damage and photoresist line or pillar collapse that often occurs during conventional EUV lithography processes.

According to one embodiment, a method is provided herein for processing a semiconductor substrate. The method may generally begin by forming a multilayer photoresist film stack on a surface of the semiconductor substrate. The multilayer photoresist film stack may generally include a first photoresist layer and a second photoresist layer formed above the first photoresist layer. The first photoresist layer may comprise a metal oxide resist material, and the second photoresist layer may comprise a resist material that differs from the metal oxide resist material used in the first photoresist layer.

After forming multilayer photoresist film stack, the method may further include exposing the multilayer photoresist film stack to extreme ultra-violet (EUV) radiation in a single exposure step to: (a) convert regions of the first photoresist layer exposed to the EUV radiation to reacted regions, while regions of the first photoresist layer not exposed to the EUV radiation remain unchanged as unreacted regions, and (b) convert regions of the second photoresist layer exposed to the EUV radiation to reacted regions, while regions of the second photoresist layer not exposed to the EUV radiation remain unchanged as unreacted regions.

After EUV exposure, the method may expose the multilayer photoresist film stack to at least two different development steps to separately, and selectively, develop the first and second photoresist layers included within the multilayer photoresist film stack. For example, the method may expose the multilayer photoresist film stack to a first development process to selectively develop the second photoresist layer by removing the reacted regions or the unreacted regions of the second photoresist layer to form a pattern in the second photoresist layer. Thereafter, the method may subsequently expose the multilayer photoresist film stack to a second development process to selectively develop the first photoresist layer by removing the reacted regions or the unreacted regions of the first photoresist layer to form a pattern in the first photoresist layer.

A wide variety of photoresist materials may be used within the first and second photoresist layers. For example, the metal oxide resist (MOR) material used in the first photoresist layer may comprise an organometallic oxide containing a central metal atom of tin (Sn), zirconium (Zr), indium (In), antimony (Sb), bismuth (Bi), zinc (Zn), hafnium (Hf), aluminum (AI), or combinations thereof. In some embodiments, the second photoresist layer may include a chemically amplified resist (CAR) material. In other embodiments, the second photoresist layer may include another metal oxide resist (MOR) material, which differs from the MOR material used in the first photoresist layer. Like the MOR material included within the first photoresist layer, the MOR material used within the second photoresist layer may contain an organometallic oxide having a central metal atom of tin (Sn), zirconium (Zr), indium (In), antimony (Sb), bismuth (Bi), zinc (Zn), hafnium (Hf), or aluminum (AI), or combinations thereof. However, when the first and second photoresist layers both include MOR materials, the organometallic oxide included within the second photoresist layer must be different from the organometallic oxide included within the first photoresist layer.

Additional layers may also be included within the multilayer photoresist film stack. In some embodiments, for example, the method may form an EUV enhancement layer on at least one underlayer provided on the surface of the semiconductor substrate before forming the first photoresist layer on the EUV enhancement layer. The EUV enhancement layer may comprise a metal or non-metal material that generates and emits secondary electrons when exposed to the EUV radiation. Thus, when an EUV enhancement layer is included within the multilayer photoresist film stack, the EUV enhancement layer may increase exposure of the first photoresist layer to the EUV radiation during the single exposure step. In some embodiments, the method may form a barrier layer on the first photoresist layer before forming the second photoresist layer on the barrier layer. The barrier layer may comprise a hydrophilic material that improves adhesion for the second photoresist layer and provides an etch stop during the first development process.

In one embodiment, the method may form the multilayer photoresist stack by: (a) forming an EUV enhancement layer on at least one underlayer provided on the surface of the semiconductor substrate, wherein the EUV enhancement layer comprises a metal or non-metal material that generates and emits secondary electrons when exposed to the EUV radiation, and wherein the EUV enhancement layer has a thickness ranging between 0.5 nm and 5 nm; (b) forming the first photoresist layer on the EUV enhancement layer, wherein the metal oxide resist material used in the first photoresist layer comprises a first organometallic oxide and has a thickness ranging between 1 nm and 15 nm; (c) forming a barrier layer on the first photoresist layer, wherein the barrier layer comprises a hydrophilic material and has a thickness ranging between about one monolayer to less than 2 nm; and (d) forming the second photoresist layer on the barrier layer, wherein the second photoresist layer comprises: (i) a chemically amplified resist (CAR) material, or (ii) a metal oxide resist material that differs from the metal oxide resist material used in the first photoresist layer, and has a thickness ranging between 1 nm and 15 nm. In such an embodiment, a combined thickness of the multilayer photoresist film stack may range between 2 nm and 35 nm.

A wide variety of development processes may be used to selectively develop the second photoresist layer and the first photoresist layer, depending on the materials used to form such layers.

When the second photoresist layer comprises a chemically amplified resist (CAR) material, for example, said exposing the multilayer photoresist film stack to the first development process may comprise exposing the multilayer photoresist film stack to a wet development process to remove the reacted regions or the unreacted regions of the second photoresist layer and form the pattern in the second photoresist layer. When a wet development process is used to selectively develop the second photoresist layer, the surface of the semiconductor substrate may be exposed to a develop solution to dissolve the reacted regions or the unreacted regions of the second photoresist layer. Examples of develop solutions that may be used in the wet development process include, but are not limited to, propylene glycol methyl ether acetate (PGMEA), tetramethylammonium hydroxide (TMAH), normal butyl alcohol (NBA), 2-heptanone and other organic solvents with an acid additive.

When the second photoresist layer comprises a metal oxide resist (MOR) material that differs from the metal oxide resist (MOR) material used in the first photoresist layer, said exposing the multilayer photoresist film stack to the first development process may comprise exposing the multilayer photoresist film stack to a dry development process to remove the reacted regions or the unreacted regions of the second photoresist layer and form the pattern in the second photoresist layer. When a dry development process is used to selectively develop the second photoresist layer, the surface of the semiconductor substrate may be exposed to one or more process gases, which react with exposed surfaces of the second photoresist layer to remove the reacted regions or the unreacted regions of the second photoresist layer. Examples of process gases that may be used in the dry development process include, but are not limited to, hydrogen (H₂), ammonia (NH₃), a halogen containing gas or combinations thereof.

When the first photoresist layer comprises a metal oxide resist (MOR) material, said exposing the multilayer photoresist film stack to the second development process may also comprise exposing the multilayer photoresist film stack to a dry development process to remove the reacted regions or the unreacted regions of the first photoresist layer and form the pattern in the first photoresist layer. When a dry development process is used to selectively develop the first photoresist layer, the surface of the semiconductor substrate may be to one or more process gases, which react with exposed surfaces of the first photoresist layer to remove the reacted regions or the unreacted regions of the first photoresist layer. Examples of process gases that may be used in the dry development process include, but are not limited to, hydrogen (H₂), ammonia (NH₃), a halogen containing gas or combinations thereof.

According to another embodiment, another method is provided herein for processing a semiconductor substrate. The method may generally begin by forming a multilayer photoresist film stack on a surface of the semiconductor substrate by: (a) depositing an extreme ultra-violet (EUV) enhancement layer on at least one underlayer provided on the surface of the semiconductor substrate; (b) depositing a first photoresist layer on the EUV enhancement layer, the first photoresist layer comprising a metal oxide resist material; (c) depositing a barrier layer on the first photoresist layer; and (d) depositing a second photoresist layer on the barrier layer, the second photoresist layer comprising a resist material that differs from the metal oxide resist material used in the first photoresist layer. In some embodiments, a combined thickness of the multilayer photoresist film stack ranges between 2 nm and 35 nm.

After forming multilayer photoresist film stack, the method may further include exposing the multilayer photoresist film stack to EUV radiation in a single exposure step to convert regions of the first photoresist layer and regions of the second photoresist layer exposed to the EUV radiation to reacted regions, while regions of the first photoresist layer and regions of the second photoresist layer not exposed to the EUV radiation remain unchanged as unreacted regions. After EUV exposure, the method may use two different development steps to selectively develop the first and second photoresist layers. For example, the method may expose the multilayer photoresist film stack to a first development process to selectively develop the second photoresist layer by removing the reacted regions or the unreacted regions of the second photoresist layer to form a pattern in the second photoresist layer. Thereafter, the method may expose the multilayer photoresist film stack to a second development process to selectively develop the first photoresist layer by removing the reacted regions or the unreacted regions of the first photoresist layer to form a pattern in the first photoresist layer. In some embodiments, said forming the multilayer photoresist film stack, said exposing the multilayer photoresist film stack to the first development process and said exposing the multilayer photoresist film stack to the second development process may form a pattern in the second photoresist layer and in the first photoresist layer that avoids pattern collapse.

In some embodiments, said depositing the first photoresist layer may include depositing the metal oxide resist material on the EUV enhancement layer, where the metal oxide resist material comprises an organometallic oxide having a thickness ranging between 1 nm and 15 nm. When the first photoresist layer comprises a MOR material, said exposing the multilayer photoresist film stack to the second development process may comprise exposing the multilayer photoresist film stack to a dry development process to remove the reacted regions or the unreacted regions of the first photoresist layer and form the pattern in the first photoresist layer.

In some embodiments, said depositing the second photoresist layer may include depositing a chemically amplified resist (CAR) material on the barrier layer, where the CAR material has a thickness ranging between 1 nm and 15 nm. When the second photoresist layer comprises a CAR material, said exposing the multilayer photoresist film stack to the first development process may include exposing the multilayer photoresist film stack to a wet development process to remove the reacted regions or the unreacted regions of the second photoresist layer and form the pattern in the second photoresist layer.

In other embodiments, said depositing the second photoresist layer may include depositing a metal oxide resist material, which differs from the metal oxide resist material used in the first photoresist layer, on the barrier layer. The metal oxide resist material used within the second photoresist layer may comprise an organometallic oxide, which differs from the organometallic oxide included within the first photoresist layer, and has a thickness ranging between 1 nm and 15 nm. When the second photoresist layer comprises a MOR material, said exposing the multilayer photoresist film stack to the first development process may include exposing the multilayer photoresist film stack to a dry development process to remove the reacted regions or the unreacted regions of the second photoresist layer and form the pattern in the second photoresist layer.

A wide variety of deposition processes may be used in the methods described herein to form the layers included within the multilayer photoresist stack. For example, the EUV enhancement layer, the first photoresist layer, the barrier layer and the second photoresist layer may each be deposited using spin coating, chemical vapor deposition (CVD) or atomic layer deposition (ALD) deposition processes. In some embodiments, one or more layers of the multilayer photoresist stack may be deposited in situ within the same process chamber. For example, at least the EUV enhancement layer, the first photoresist layer and the barrier layer may be deposited in situ using the same deposition technique, in some embodiments. Other deposition processes not specifically mentioned herein may also be used.

The methods described herein can be used to form negative tone or positive tone photoresist patterns on the semiconductor substrate. In some embodiments, the first photoresist layer and the second photoresist layer may each comprise a negative photoresist, and the EUV exposure and development steps may be performed to form a negative tone EUV photoresist pattern on the substrate. In other embodiments, the first photoresist layer may comprise a negative photoresist and the second photoresist may comprise a positive photoresist, and the EUV exposure and development steps may be performed to form a positive tone EUV photoresist pattern on the substrate.

Various embodiments of methods are provided herein for processing a semiconductor substrate, and more specifically, for forming an EUV photoresist pattern on a semiconductor substrate. Of course, the order of discussion of the different steps as described herein has been presented for the sake of clarity. In general, these steps can be performed in any suitable order. Additionally, although each of the different features, techniques, configurations, etc. herein may be discussed in different places of this disclosure, it is intended that each of the concepts can be executed independently of each other or in combination with each other. Accordingly, the present invention can be embodied and viewed in many different ways.

Note that this summary section does not specify every embodiment and/or incrementally novel aspect of the present disclosure or claimed inventions. Instead, this summary only provides a preliminary discussion of different embodiments and corresponding points of novelty over conventional techniques. For additional details and/or possible perspectives of the invention and embodiments, the reader is directed to the Detailed Description section and corresponding figures of the present disclosure as further discussed below.

### BRIEF DESCRIPTION OF THE DRAWINGS

A more complete understanding of the present inventions and advantages thereof may be acquired by referring to the following description taken in conjunction with the accompanying drawings, in which like reference numbers indicate like features. It is to be noted, however, that the accompanying drawings illustrate only exemplary embodiments of the disclosed concepts and are therefore not to be considered limiting of the scope, for the disclosed concepts may admit to other equally effective embodiments.

FIG. 1 is a flowchart diagram illustrating a method for processing a semiconductor substrate in accordance with one embodiment of the present disclosure.

FIG. 2 illustrates one example of a process flow that utilizes the method shown in FIG. 1 to form an EUV photoresist pattern on a semiconductor substrate, according to a first embodiment of the present disclosure.

FIG. 3 illustrates another example of a process flow that utilizes the method shown in FIG. 1 to form an EUV photoresist pattern on a semiconductor substrate, according to a second embodiment of the present disclosure.

FIG. 4 is a flowchart diagram illustrating another method for processing a semiconductor substrate in accordance with another embodiment of the present disclosure.

FIG. 5 illustrates one example of a process flow that utilizes the method shown in FIG. 4 to form an EUV photoresist pattern on a semiconductor substrate, according to a third embodiment of the present disclosure.

FIG. 6 illustrates another example of a process flow that utilizes the method shown in FIG. 4 to form an EUV photoresist pattern on a semiconductor substrate, according to a fourth embodiment of the present disclosure.

### DETAILED DESCRIPTION OF ILLUSTRATIVE EMBODIMENTS

Embodiments of the present disclosure provide improved process flows and methods for processing a semiconductor substrate. More specifically, the present disclosure provides improved process flows and methods that utilize a multilayer photoresist film stack to form an extreme ultra-violet (EUV) photoresist pattern on a semiconductor substrate. The multilayer photoresist film stack disclosed herein includes a plurality of relatively thin photoresist film layers, each layer comprising a different photoresist material.

In the disclosed embodiments, a multilayer photoresist film stack is deposited on at least one underlayer formed above a semiconductor substrate and patterned using EUV lithography to form an EUV photoresist pattern on the underlayer(s). The multilayer photoresist film stack deposited on the underlayer(s) includes at least a first photoresist layer and a second photoresist layer formed above the first photoresist layer. The first and second photoresist layers are relatively thin photoresist films (having, e.g., a film thickness less than 15 nm) formed from different photoresist materials. A wide variety of photoresist materials may be used within the multilayer photoresist film stack. For example, the first photoresist layer may include a metal oxide resist (MOR) material and the second photoresist layer may include a chemically amplified resist (CAR) material or another MOR material, which differs from the MOR material used in the first photoresist layer. Although MOR and CAR resists are provided herein as examples, other EUV-active photoresist materials may also be utilized within the multilayer photoresist film stack.

The improved processes and methods disclosed herein provide a multilayer photoresist film stack for use in EUV lithography. In the disclosed embodiments, the multilayer photoresist film stack is exposed to EUV radiation to convert portions of the first and second photoresist layers to reacted photoresist in a single exposure step. After EUV exposure, the multilayer photoresist film stack is exposed to at least two different development steps to selectively develop the first and second photoresist layers included within the multilayer photoresist film stack. Because the first and second photoresist layers are implemented with different photoresist materials, each photoresist layer is selectively developed, one at a time, to mitigate pattern collapse.

The processes and methods disclosed herein overcome the challenges typically faced when conventional EUV lithography are used to form a photoresist pattern on a semiconductor substrate. As noted above and described further below, a plurality of relatively thin, yet different, photoresist film layers are combined within a multilayer photoresist film stack to increase the overall resist film thickness. By combining different photoresist layers within a multilayer photoresist film stack, and using two different development steps to selectively develop the different photoresist layers, the processes and methods disclosed herein avoid the photoresist damage and photoresist line or pillar collapse that often occurs during conventional EUV lithography processes.

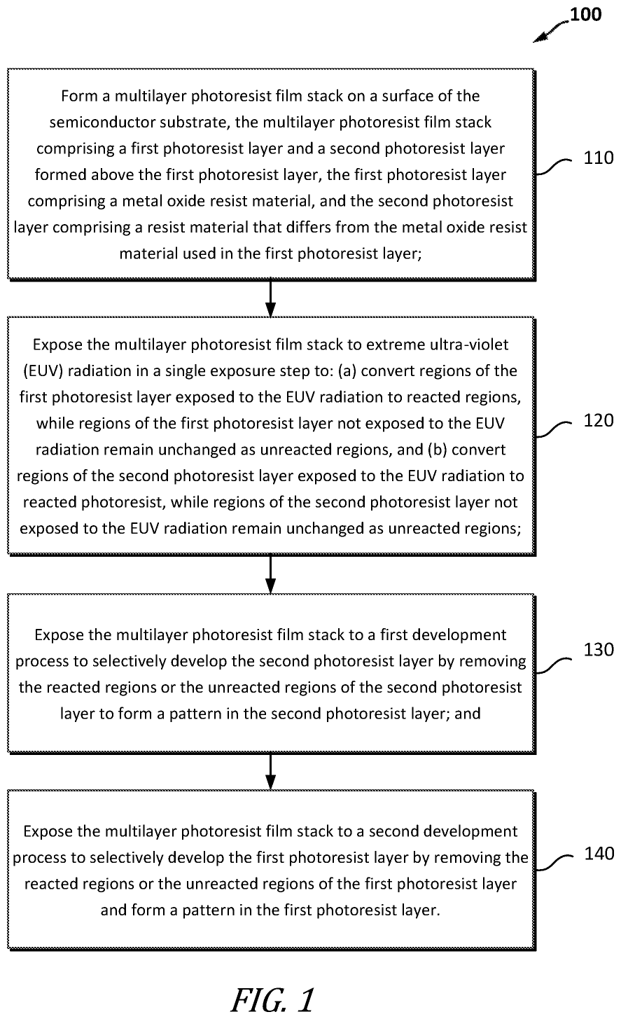

Turning now to the Drawings, FIG. 1 illustrates one embodiment of a method for processing a semiconductor substrate in accordance with the present disclosure. More specifically, FIG. 1 illustrates one embodiment of a method that utilizes a multilayer photoresist film stack to pattern a semiconductor substrate in an EUV photolithographic process. It will be recognized that the embodiment of FIG. 1 is merely exemplary and additional methods may utilize the techniques described herein. Further, additional processing steps may be added to the method shown in the FIG. 1 as the steps described are not intended to be exclusive. Moreover, the order of the steps is not limited to the order shown in the figures as different orders may occur and/or various steps may be performed in combination or at the same time.

The method 100 shown in FIG. 1 begins by forming a multilayer photoresist film stack on a surface of a semiconductor substrate (in step 110). The multilayer photoresist film stack formed in step 110 includes at least a first photoresist layer and a second photoresist layer formed above the first photoresist layer. In the embodiment shown in FIG. 1, the first photoresist layer includes a metal oxide resist material, and the second photoresist layer includes a resist material that differs from the metal oxide resist material used in the first photoresist layer. Regardless of the particular material used, the first photoresist layer and the second photoresist layer may each be relatively thin layers. For example, the first photoresist layer and the second photoresist layer may each have a thickness ranging between 1 nm and 15 nm. In some embodiments, the multilayer photoresist film stack formed in step 110 may further include an EUV enhancement layer formed under the first photoresist layer and/or a barrier layer formed between the first photoresist layer and the second photoresist layer, as discussed further herein.

After the multilayer photoresist film stack is formed in step 110, the method 100 exposes the multilayer photoresist film stack to EUV radiation in a single exposure step (in step 120) to: (a) convert regions of the first photoresist layer exposed to the EUV radiation to reacted regions, while regions of the first photoresist layer not exposed to the EUV radiation remain unchanged as unreacted regions, and (b) convert regions of the second photoresist layer exposed to the EUV radiation to reacted regions, while regions of the second photoresist layer not exposed to the EUV radiation remain unchanged as unreacted regions. The process conditions utilized during the EUV exposure step (e.g., EUV dose and exposure time) may generally be selected to ensure that regions of the first photoresist layer and the second photoresist layer not covered by an overlying photomask are adequately exposed to EUV radiation to convert the exposed regions into reacted photoresist in a single exposure step. In some embodiments, an optional post-exposure bake (PEB) step (or other heat-treating step) may be performed to stabilize the photoresist after EUV exposure by completing the reactions initiated during EUV exposure.

After EUV exposure (and optional PEB), the method 100 exposes the multilayer photoresist film stack to at least two different development steps to separately, and selectively, develop the first and second photoresist layers included within the multilayer photoresist film stack. For example, the method 100 may expose the multilayer photoresist film stack to a first development process to selectively develop the second photoresist layer by removing the reacted regions or the unreacted regions of the second photoresist layer to form a pattern in the second photoresist layer (in step 130). After the first development process is complete, the method 100 may expose the multilayer photoresist film stack to a second development process to selectively develop the first photoresist layer by removing the reacted regions or the unreacted regions of the first photoresist layer to form a pattern in the first photoresist layer (in step 140).

A wide variety of semiconductor materials may be used to implement the substrate, the first photoresist layer, and the second photoresist layer in the method 100 shown in FIG. 1. Examples of suitable semiconductor materials are provided below for explanatory purposes. However, one skilled in the art having the benefit of this disclosure would readily understand how other semiconductor materials not specifically mentioned herein may also be utilized.

The semiconductor substrate may be any substrate for which patterning of the substrate is desirable. For example, the substrate may be a semiconductor substrate having one or more semiconductor processing layers (all of which together may comprise the substrate) formed thereon. Thus, in one embodiment, the substrate may be a semiconductor substrate that has been subject to multiple semiconductor processing steps which yield a wide variety of structures and layers, all of which are known in the substrate processing art, and which may be considered to be part of the substrate. For example, in one embodiment, the substrate may be a semiconductor wafer having one or more semiconductor processing layers formed thereon. The concepts disclosed herein may be utilized at any stage of the substrate process flow such as, for example, any of the numerous deposition, photolithography and etching steps that may be utilized to form a completed substrate.

A wide variety of photoresist materials may be used within the first and second photoresist layers. In some embodiments, the first photoresist layer may include a metal oxide resist (MOR) material containing an organometallic oxide. In one example, the MOR material used within the first photoresist layer may be an organometallic oxide comprising tin oxide (SnO). It is noted, however, that the MOR material used within the first photoresist layer is not limited to such an example and may include other organometallic oxides having a central metal atom of tin (Sn), zirconium (Zr), indium (In), antimony (Sb), bismuth (Bi), zinc (Zn), hafnium (Hf), aluminum (Al) or combinations thereof. It is further noted that the first photoresist layer disclosed herein is not strictly limited to organometallic oxides, and may include other organic and inorganic photoresist film layers that are suitable for EUV lithography.

As noted above, the second photoresist layer may generally include a resist material that differs from the MOR material used in the first photoresist layer. In some embodiments, the second photoresist layer may include a chemically amplified resist (CAR) material. Chemically amplified resists (CARs) generally include a polymer resin, a photoacid generator (PAG) to provide sensitivity to UV light and a dissolution inhibitor to provide a solubility switch before and after UV exposure. Examples of CAR materials suitable for use in EUV lithography include, but are not limited to, polymethylmethacrylate (PMMA), a polyhydroxystyrene (PHS), and other materials commonly used for CARS.

In other embodiments, the second photoresist layer may include another metal oxide resist (MOR) material, which differs from the MOR material used in the first photoresist layer. Like the MOR material included within the first photoresist layer, the MOR material used within the second photoresist layer may contain an organometallic oxide having a central metal atom of tin (Sn), zirconium (Zr), indium (In), antimony (Sb), bismuth (Bi), zinc (Zn), hafnium (Hf), or aluminum (AI), or combinations thereof. When the first and second photoresist layers both include MOR materials, it is necessary for the organometallic oxide included within the second photoresist layer to be different from the organometallic oxide included within the first photoresist layer. In one example, the MOR material used in the second photoresist layer may be an organometallic oxide comprising titanium oxide (TiO) or another organometallic oxide that differs from the organometallic oxide (e.g., SnO) used in the first photoresist layer. Although MOR and CAR resists are provided herein as examples, other EUV-active photoresist materials may also be used to implement the second photoresist layer.

The first and second photoresist layers may each comprise negative or positive photoresist materials. As known in the art, a negative photoresist (or negative tone resist) is a photosensitive material that is strengthened (either polymerized or cross-linked) when exposed to light, rendering the exposed portions of the material in-soluble (or less soluble) in the develop solution or more difficult to remove in a dry development process. A positive photoresist (or positive tone resist) is a photosensitive material that is weakened or degraded by light, rendering the exposed portions of the material soluble (or more soluble) in the develop solution or easier to remove in a dry development process. The MOR and CAR resists described above may be negative photoresists, positive photoresists or a combination of negative and positive photoresists, depending on the particular photoresistive materials included within the photoresist layers.

In some embodiments, the multilayer photoresist film stack formed in step 110 may further include an EUV enhancement layer formed under the first photoresist layer and/or a barrier layer formed between the first photoresist layer and the second photoresist layer, as noted above. For example, the method 100 may: (a) form an EUV enhancement layer on at least one underlayer provided on the surface of the semiconductor substrate before forming the first photoresist layer on the EUV enhancement layer, and/or (b) form a barrier layer on the first photoresist layer before forming the second photoresist layer on the barrier layer.

The underlayer(s) formed on and/or above the semiconductor substrate may include one or more underlayers commonly used for patterning. Examples of underlayer(s) include, but are not limited to, bottom anti-reflective coating (BARC) layers, hard mask layers, carbon layers and other organic and inorganic material layers. For example, the underlayer(s) may include a carbon (C) layer, an amorphous carbon layer (a-C), a silicon carbide (SiC) layer, a silicon oxycarbide (SiOC) layer, a silicon carbide (SiC) layer, an amorphous silicon (a-Si) layer, a silicon dioxide (SiO₂) layer and/or combinations thereof. Other semiconductor materials suitable for use as underlayers may also be utilized, as discussed further herein and known in the art.

In some embodiments, the EUV enhancement layer may be included within the multilayer photoresist film stack to increase exposure of the first photoresist layer to the EUV radiation during the single exposure step (in step 120). The EUV enhancement layer may generally include materials having high electron emission when exposed to EUV radiation. As such, the EUV enhancement layer may enhance exposure dose via secondary electron generation upon EUV exposure. Examples of such materials include, but are not limited to, metals and non-metal materials, such as transition metals, lanthanides and graphitic materials (e.g., graphene). In some embodiments, inclusion of the EUV enhancement layer within the multilayer photoresist film stack may enable the EUV dose to be reduced and/or provide scaling. The secondary electrons emitted by the EUV enhancement layer facilitate further reactions in the first photoresist layer, thereby improving the exposed area and reducing the required EUV dose.

In some embodiments, the barrier layer may be included within the multilayer photoresist film stack to improve adhesion for the second photoresist layer and provide an etch stop during the first development process (in step 130). The barrier layer may generally include a hydrophilic material or another material that provides good adhesion between the first and second photoresist layers, especially when the first photoresist layer is a MOR and the second photoresist layer is a CAR. As used herein, a hydrophilic material is defined as a material having a water contact angle less than or equal to 60°. Examples of hydrophilic materials suitable for use as a barrier layer include, but are not limited to, amorphous carbon (a-C), silicon oxycarbide (SiOC), amorphous silicon, silicon dioxide (SiO₂) and other metal containing materials having properties that provide good adhesion for the second photoresist layer.

A wide variety of deposition processes may be used to form the layers included within the multilayer photoresist stack (in step 110). For example, the EUV enhancement layer, the first photoresist layer, the barrier layer and the second photoresist layer may each be deposited using spin coating, chemical vapor deposition (CVD) or atomic layer deposition (ALD) deposition processes. In some embodiments, one or more layers of the multilayer photoresist stack may be deposited in situ within the same process chamber. For example, at least the EUV enhancement layer, the first photoresist layer and the barrier layer may be deposited in situ using the same deposition technique, in some embodiments. Other deposition processes not specifically mentioned herein may also be used.

A wide variety of development processes may be used to selectively develop the second photoresist layer (in step 130) and selectively develop the first photoresist layer (in step 140), depending on the resist materials used within the first and second photoresist layers. In some embodiments, the method 100 may use a combination of wet and dry development processes to selectively develop the second photoresist layer (in step 130) and selectively develop the first photoresist layer (in step 140). In other embodiments, a combination of two or more wet development processes, or two or more dry development processes, may be used to selectively develop the second photoresist layer (in step 130) and selectively develop the first photoresist layer (in step 140).

In one example embodiment, the second photoresist layer may include a CAR material, and the method 100 may expose the multilayer photoresist film stack to a wet development process (in step 130) to remove the reacted regions (or the unreacted regions) of the second photoresist layer and form the pattern in the second photoresist layer. During a wet development process, the surface of the substrate is treated with a develop solution to dissolve the reacted regions (in case of a positive tone resist) or unreacted regions (in case of a negative tone resist) of the post-exposure, second photoresist layer. The develop solution supplied to the substrate surface may generally depend on the resist material used within the second photoresist layer. Examples of develop solutions that may be used to selectively develop the second photoresist layer include, but are not limited to, propylene glycol methyl ether acetate (PGMEA), tetramethylammonium hydroxide (TMAH), normal butyl alcohol (NBA), 2-heptanone and other organic solvents with an acid additive.

In another example embodiment, the second photoresist layer may include a MOR material, and the method 100 may expose the multilayer photoresist film stack to a dry development process (in step 130) to remove the reacted regions (or the unreacted regions) of the second photoresist layer and form the pattern in the second photoresist layer. The dry development process may comprise, for example, a selective plasma etch process or a thermal process, advantageously eliminating the use of a developing solution. In certain embodiments, the dry development process may be performed using reactive ion etching (RIE), atomic layer etching (ALE) or chemical vapor etching (CVE).

During a dry development process, the surface of the substrate is exposed to one or more process gases, which react with the exposed surfaces of the second photoresist layer to remove the reacted regions (in case of a positive tone resist) or unreacted regions (in case of a negative tone resist) of the post-exposure, second photoresist layer. A wide variety of process gases (and optionally non-reactive gases) may be used in the dry development process to selectively develop the second photoresist layer. Examples of process gases that may be used to selectively develop the second photoresist layer include, but are not limited to, hydrogen (H₂), ammonia (NH₃), halogen containing process gases (e.g., process gases containing chlorine, fluorine, bromine, etc.) and/or combinations thereof. Examples of non-reactive gases that may be combined with one or more process gases include, but are not limited to, argon (Ar) and nitrogen (N₂).

In one example embodiment, the method 100 may expose the multilayer photoresist film stack to a dry development process (in step 140) to remove the reacted regions or the unreacted regions of the first photoresist layer and form the pattern in the first photoresist layer. During the dry development process, the surface of the substrate is exposed to one or more process gases, which react with the exposed surfaces of the first photoresist layer to remove the reacted regions (in case of a positive tone resist) or unreacted regions (in case of a negative tone resist) of the post-exposure, first photoresist layer. A wide variety of process gases (and optionally non-reactive gases) may be used in the dry development process to selectively develop the first photoresist layer, as discussed above in reference to the second photoresist layer.

In certain embodiments, wet development processes are generally preferred when developing CAR materials, due to the ease with which post-exposure CAR materials are removed with developing solutions, whereas dry development processes are generally preferred when developing MOR materials. When a MOR material is used in the first photoresist layer and a CAR material is used in the second photoresist layer, the dry development process used in step 140 improves development selectivity between the CAR and MOR materials. When different MOR materials are used in the first and second photoresist layers, the dry development processes used in steps 130 and 140 may utilized different process gases to selectively develop the first and second photoresist layers.

The method 100 shown in FIG. 1 improves upon conventional EUV photolithographic processes by: (a) providing a multilayer photoresist film stack comprising at least two different relatively thin photoresist film layers (e.g., each photoresist film may have a film thickness <15 nm), and (b) using two different development steps to selectively develop the different photoresist film layers. In doing so, the method 100 avoids the pattern collapse that often occurs when a relatively thick photoresist film layer (e.g., a photoresist film having a film thickness >20 nm) is developed in a single wet or dry development step, and avoids damaging the photoresist film stack when transferring the photoresist pattern to underlying target layer(s).

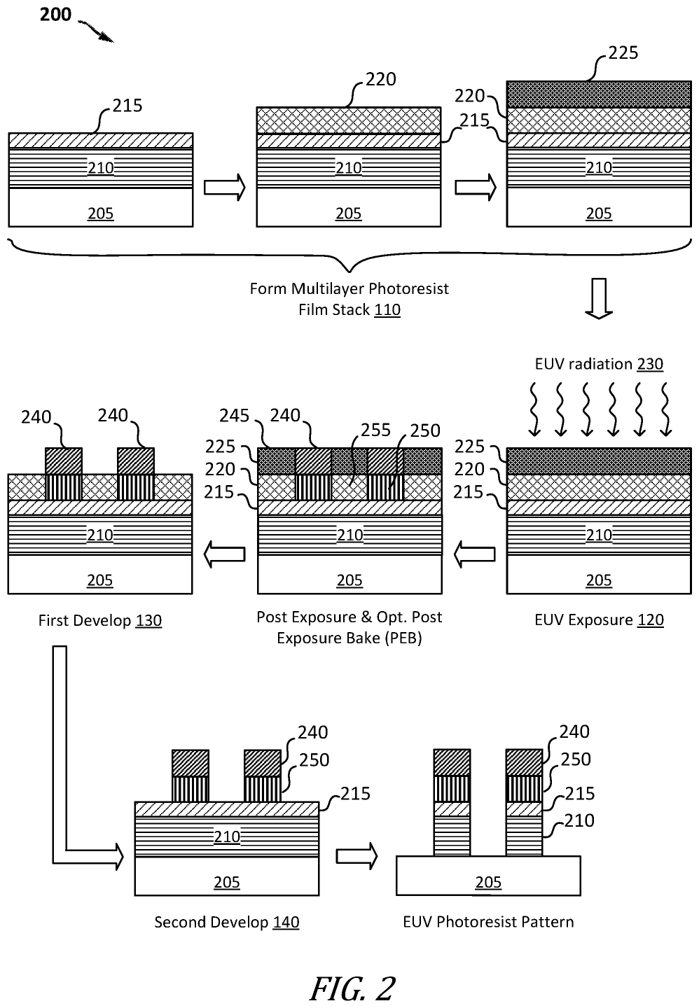

FIG. 2 illustrates one example of a process flow 200 that utilizes the method 100 shown in FIG. 1 to form an EUV photoresist pattern on a semiconductor substrate in accordance with a first embodiment of the present disclosure. Like the method 100 described above, the process flow 200 begins by forming a multilayer photoresist film stack on a surface of a semiconductor substrate 205 (in step 110). In the process flow 200 shown in FIG. 2, the multilayer photoresist film stack is formed in step 110 by: (a) depositing an EUV enhancement layer 215 on at least one underlayer 210 provided on the surface of the semiconductor substrate 205; (b) depositing a first photoresist layer 220 on the EUV enhancement layer 215; and (c) depositing a second photoresist layer 225 on the first photoresist layer 220.

The at least one underlayer 210 may generally include one or more underlayers, such as an under layer (UL), a middle layer (ML) and/or a bottom layer (BL). Examples of UL, ML and BL materials include, but are not limited to, amorphous carbon for UL materials, oxides (such as silicon oxides) for ML materials and nitrides (such as titanium nitride) for BL materials. Other UL, ML and BL materials may be used, as is known in the art. As noted above, the EUV enhancement layer 215 deposited on at least one underlayer 210 may include a metal or non-metal material, which demonstrates high electron emission when exposed to EUV radiation. Examples of such materials include, but are not limited to, metals (e.g., transition metals and lanthanides) and graphitic materials such as, for example, graphene. In some embodiments, a thickness of the EUV enhancement layer 215 may range between 0.5 nm and 5 nm.

In some embodiments, the first photoresist layer 220 deposited on top of the EUV enhancement layer 215 may include a metal oxide resist (MOR) material containing a first organometallic oxide. In one example embodiment, the first photoresist layer 220 may be a negative tone resist comprising tin oxide (SnO). It is noted, however, that the first photoresist layer 220 is not strictly limited to such an example and may alternatively include other negative or positive photosensitive materials comprising other organometallic oxides such as, but not limited to, zirconium oxide (ZrO), indium oxide (InO), antimony oxide (SbO), bismuth oxide (BiO), zinc oxide (ZnO), hafnium oxide (HfO), aluminum oxide (AIO) and metal oxide frameworks (MOFs). The first photoresist layer 220 may include a relatively thin photoresist film (e.g., a photoresist film having a film thickness <15 nm). In some embodiments, a thickness of the first photoresist layer 220 may range between 1 nm and 15 nm.

The second photoresist layer 225 deposited above the first photoresist layer 220 includes a resist material, which differs from the MOR material used in the first photoresist layer 220. For example, the second photoresist layer 225 may include a chemically amplified resist (CAR) material or a MOR material that differs from the MOR material used in the first photoresist layer 220. The CAR or MOR material may be a negative or positive photosensitive material. In one example, the MOR material used in the second photoresist layer 225 may be another negative tone resist comprising a second organometallic oxide (such as, e.g., titanium oxide (TiO) or another organometallic oxide) that differs from the first organometallic oxide (e.g., tin oxide (SnO)) used in the first photoresist layer 220. The second photoresist layer 225 may include a relatively thin photoresist film (e.g., a photoresist film having a film thickness <15 nm). In some embodiments, a thickness of the second photoresist layer 225 may range between 1 nm and 15 nm.

The multilayer photoresist film stack shown in FIG. 2, which includes EUV enhancement layer 215, first photoresist layer 220 and second photoresist layer 225, may have a combined thickness ranging between 2 nm and 30 nm. The use of two different photoresist layers 220/225 increases resist thickness, while mitigating pattern collapse concerns. In some embodiments, the combined thickness of the multilayer photoresist film stack may enable the overall thickness of the stack to be reduced by eliminating one or more of the underlayers. For example, the UL and/or the ML may be omitted from the at least one underlayer 210 when the multilayer photoresist film stack shown in FIG. 2 is utilized to form an EUV pattern.

The at least one underlayer 210, the EUV enhancement layer 215, the first photoresist layer 220 and the second photoresist layer 225 may each be deposited using a wide variety of wet or dry deposition processes. For example, the at least one underlayer 210, the EUV enhancement layer 215, the first photoresist layer 220 and the second photoresist layer 225 may be deposited using spin coating, chemical vapor deposition (CVD) or atomic layer deposition (ALD) deposition processes. In some embodiments, one or more layers of the multilayer photoresist stack may be deposited in situ within the same process chamber. For example, at least the EUV enhancement layer 215, the first photoresist layer 220 and the barrier layer 222 may be deposited in situ using the same deposition technique, in some embodiments. Other deposition processes not specifically mentioned herein may also be used.

After forming the multilayer photoresist film stack (in step 110), the process flow 200 uses EUV lithography to pattern the multilayer photoresist film stack and form an EUV photoresist pattern on the semiconductor substrate 205. As shown in FIG. 2, the EUV lithography process exposes the semiconductor substrate 205 containing the multilayer photoresist film stack to EUV radiation 230 (for example, at a wavelength of 13.5 nm) in a single EUV exposure step 120. The EUV lithography process may utilize a photomask (not shown) such that a photo-induced reaction occurs only in regions 240 of the second photoresist layer 225 and regions 250 of the first photoresist layer 220 that are exposed to the EUV radiation 230. The regions 240 of the second photoresist layer 225 and the regions 250 of the first photoresist layer 220 exposed to the EUV radiation 230 are converted to reacted photoresist. The regions 245 of the second photoresist layer 225 and regions 255 of the first photoresist layer 220, which are not exposed to the EUV radiation 230, remain unchanged as unreacted regions. After the EUV exposure step 120, an optional post-exposure bake (PEB) step may be performed to stabilize the photoresist layers after EUV exposure by completing the reactions initiated during exposure. In some embodiments, the optional PEB step may prevent changes in line edge roughness (LER), line width roughness (LWR) and/or critical dimension (CD).

The process conditions utilized during the EUV exposure step 120 (e.g., EUV dose and exposure time) may generally be selected to ensure that the regions 240 of the second photoresist layer 225 and regions 250 the first photoresist layer 220 not covered by the overlying photomask are adequately exposed to the EUV radiation 230 to convert the exposed regions into reacted photoresist in a single exposure step. For example, an EUV dose less than 70 millijoules (mJ) per cm² may be used during the EUV exposure step 120 to convert the exposed regions 240/250 of the photoresist layers to reacted photoresists. The EUV enhancement layer 215 included within the multilayer photoresist film stack increases exposure of the first photoresist layer 220 to the EUV radiation 230 during the single EUV exposure step 120. In some embodiments, inclusion of the EUV enhancement layer 215 within the multilayer photoresist film stack may enable the EUV dose to be reduced.

After completing the EUV exposure step 120 and the optional PEB step, a first development process is performed (in step 130) to remove the reacted regions (in case of a positive tone resist) or the unreacted regions (in case of a negative tone resist) of the second photoresist layer 225 and form a pattern in the second photoresist layer 225. The first development process may be a wet development process or a dry development process, depending on the resist material used in the second photoresist layer 225. In one example, a portion of the second photoresist layer 225 may be removed by treating the substrate with a develop solution (e.g., PGMEA, TMAH, etc.) to dissolve the reacted regions 240 (in case of a positive tone resist) or unreacted regions 245 (in case of a negative tone resist) of the second photoresist layer 225 when the second photoresist layer 225 includes a CAR material. Alternately, a dry development process may be used to remove the reacted regions 240 or unreacted regions 245 of the second photoresist layer 225 when the second photoresist layer 225 includes a MOR material.

Regardless of whether a wet or dry process is used, the first development process performed in step 130 selectively develops the second photoresist layer 225 by removing select portions of the second photoresist layer 225 without reacting with or removing any portion of the first photoresist layer 220 underlying the second photoresist layer 225. In the process flow 200 shown in FIG. 2, the first development process performed in step 130 selectively develops the second photoresist layer 225 by removing the unreacted regions 245 of the second photoresist layer 225 to form a negative tone resist pattern in the second photoresist layer 225. However, one skilled in the art would readily understand how the first development process could be modified to remove the reacted regions 240 of the second photoresist layer 225 to form a positive tone resist pattern in the second photoresist layer 225.

After selectively developing the second photoresist layer 225, a second development process is performed (in step 140) to remove the reacted regions (in case of a positive tone resist) or the unreacted regions (in case of a negative tone resist) of the first photoresist layer 220 and form a pattern in the first photoresist layer 220. The second development process may be a wet development process or a dry development process, depending on the resist material used in the first photoresist layer 220. In one example, a dry development process may be used to remove the reacted regions 250 (in case of a positive tone resist) or unreacted regions 255 (in case of a negative tone resist) of the first photoresist layer 220 when the first photoresist layer 220 includes a MOR material.

Like the first development process, the second development process performed in step 140 selectively develops the first photoresist layer 220 by removing select portions of the first photoresist layer 220 without reacting with or removing any portion of the second photoresist layer 225 overlying the first photoresist layer 220. In the process flow 200 shown in FIG. 2, the second development process performed in step 140 selectively develops the first photoresist layer 220 by removing the unreacted regions 255 of the first photoresist layer 220 to form a negative tone resist pattern in the first photoresist layer 220. However, one skilled in the art would readily understand how the second development process could be modified to remove the reacted regions 250 of the first photoresist layer 220 to form a positive tone resist pattern in the first photoresist layer 220. After selectively developing the first photoresist layer 220, additional processing step(s) may be performed to transfer the resist pattern to the at least one underlayer 210, thereby forming an EUV photoresist pattern on the semiconductor substrate 205. The semiconductor substrate 205 may generally include one or more target layers for pattern transfer.

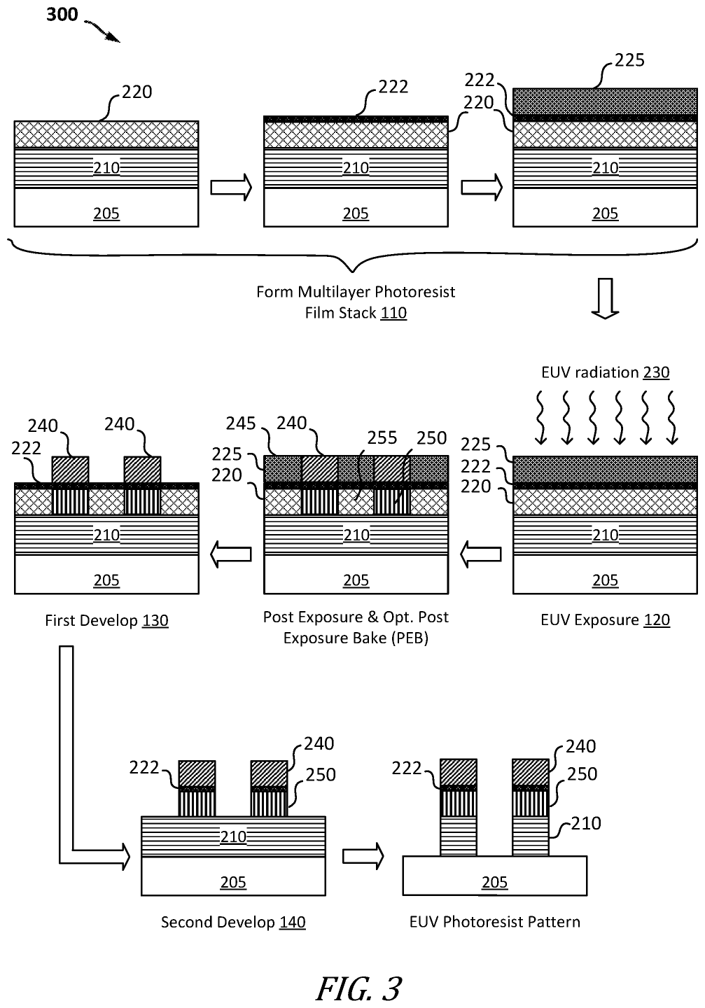

FIG. 3 illustrates another example of a process flow 300 that utilizes the method 100 shown in FIG. 1 to form an EUV photoresist pattern on a semiconductor substrate, according to a second embodiment of the present disclosure. Many of the process flow 300 steps shown in FIG. 3 are identical to the process flow 200 steps shown in FIG. 2, and thus, will not be repeated herein for the purpose of brevity. The process flow 300 differs from the process flow 200 by omitting the EUV enhancement layer 215 and adding a barrier layer 222 between the first photoresist layer 220 and the second photoresist layer 225.

As noted above, the barrier layer 222 improves adhesion for the second photoresist layer 225 and provides an etch stop during the first development process (in step 130). In some embodiments, the barrier layer 222 may be included within the multilayer photoresist film stack when the first photoresist layer 220 includes a MOR material and the second photoresist layer 225 includes a CAR material. The barrier layer 222 may include a wide variety of hydrophilic materials or other materials that provide good adhesion between the first and second photoresist layers. Examples of hydrophilic materials suitable for use within the barrier layer 222 include, but are not limited to, amorphous carbon (a-C), silicon oxycarbide (SiOC), amorphous silicon, silicon dioxide (SiO₂) and other metal containing materials having properties that provide good adhesion for the second photoresist layer 225. In some embodiments, a thickness of the barrier layer 222 may range between about one monolayer to less than 2 nm.

Depending on the material used for the barrier layer 222, at least portions of the barrier layer 222 may be removed during the first development process (in step 130) or during the second development process (in step 140). In the embodiment shown in FIG. 3, portions of the barrier layer 222 not covered by the pattern formed in the second photoresist layer 225 may be removed during the second development process (in step 140). Alternatively, exposed portions of the barrier layer 222 may be removed during the first development process (in step 130).

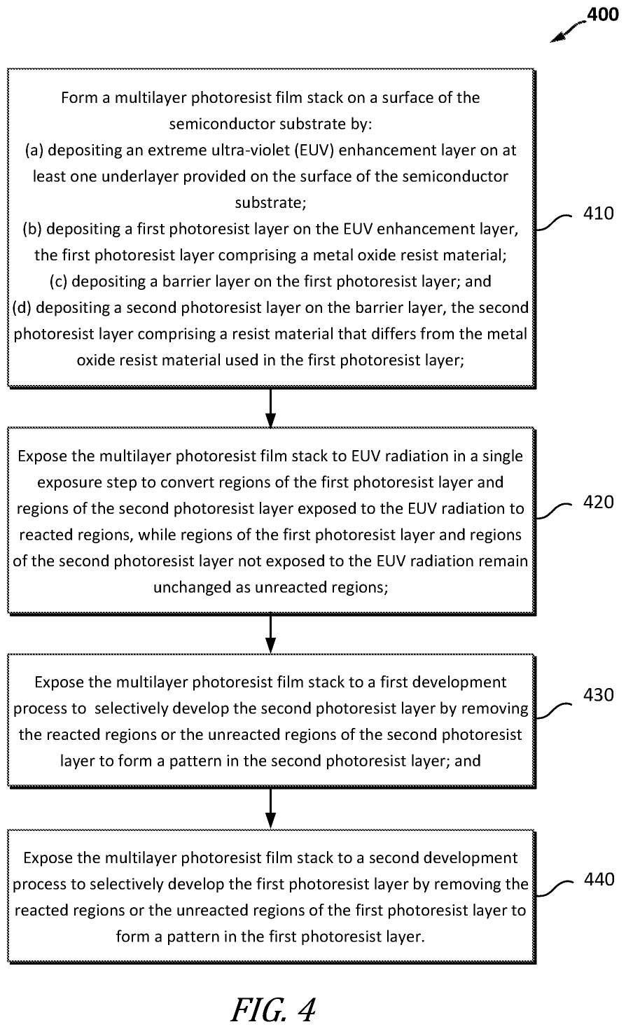

FIG. 4 illustrates another method 400 for processing a semiconductor substrate in accordance with the present disclosure. More specifically, FIG. 4 illustrates another method 400 that can be used to form an EUV photoresist pattern on a semiconductor substrate in accordance with the present disclosure. It will be recognized that the embodiment of the method 400 shown in FIG. 4 is merely exemplary and additional methods may utilize the techniques described herein. Further, additional processing steps may be added to the method 400 shown in FIG. 4 as the steps described are not intended to be exclusive. Moreover, the order of the steps is not limited to the order shown in the figure as different orders may occur and/or various steps may be performed in combination or at the same time.

Like the previous method 100 shown in FIG. 1, the method 400 shown in FIG. 4 includes forming a multilayer photoresist film stack on a surface of the semiconductor substrate (in step 410), exposing the multilayer photoresist film stack to extreme ultra-violet (EUV) radiation (in step 420), exposing the multilayer photoresist film stack to a first development process (in step 430) and exposing the multilayer photoresist film stack to a second development process (in step 440).

In the method 400, the multilayer photoresist film stack is formed in step 410 by: (a) depositing an EUV enhancement layer on at least one underlayer provided on the surface of the semiconductor substrate; (b) depositing a first photoresist layer on the EUV enhancement layer; (c) depositing a barrier layer on the first photoresist layer; and (d) depositing a second photoresist layer on the barrier layer. The EUV enhancement layer, the first photoresist layer, the barrier layer and the second photoresist layer may comprise various materials and layer thicknesses, as described above in reference to FIGS. 1-3.

After forming the multilayer photoresist film stack (in step 410), the method 400 exposes the multilayer photoresist film stack to EUV radiation in a single exposure step (in step 420) to convert regions of the first photoresist layer and regions of the second photoresist layer exposed to the EUV radiation to reacted regions, while regions of the first photoresist layer and regions of the second photoresist layer not exposed to the EUV radiation remain unchanged as unreacted regions. After EUV exposure (and optional PEB), the method 400 exposes the multilayer photoresist film stack to at least two different development steps to separately, and selectively, develop the first and second photoresist layers included within the multilayer photoresist film stack.

For example, the method 400 exposes the multilayer photoresist film stack to a first development process to selectively develop the second photoresist layer by removing the reacted regions (in case of a positive tone resist) or the unreacted regions (in case of a negative tone resist) of the second photoresist layer to form a pattern in the second photoresist layer (in step 430). After the first development process is complete, the method 400 exposes the multilayer photoresist film stack to a second development process to selectively develop the first photoresist layer by removing the reacted regions (in case of a positive tone resist) or the unreacted regions (in case of a negative tone resist) of the first photoresist layer to form a pattern in the first photoresist layer (in step 440).

A wide variety of development processes may be used to selectively develop the second photoresist layer (in step 430) and selectively develop the first photoresist layer (in step 440), depending on the resist materials used within the first and second photoresist layers. In some embodiments, the method 100 may use a combination of wet and dry development processes to selectively develop the second photoresist layer (in step 430) and selectively develop the first photoresist layer (in step 440). For example, when a CAR material is used in the second photoresist layer and a MOR material is used in the first photoresist layer, a wet development process may be used in step 430 to develop the CAR material and a dry development process may be used in step 440 to develop the MOR material. The use of different development processes in steps 430 and 440 improves development selectivity between the CAR and MOR materials. In other embodiments, a combination of two or more wet development processes, or two or more dry development processes, may be used to selectively develop the second photoresist layer (in step 430) and selectively develop the first photoresist layer (in step 440). For example, when different MOR materials are used in the first and second photoresist layers, dry development processes utilizing different process gases may be used in steps 430 and 440 to selectively develop the first and second photoresist layers.

Like the method 100 shown in FIG. 1, the method 400 shown in FIG. 4 improves upon conventional EUV photolithographic processes by: (a) providing a multilayer photoresist film stack comprising at least two different relatively thin photoresist film layers (e.g., each photoresist film may have a film thickness <15 nm), and (b) using two different development steps to selectively develop the different photoresist film layers. In doing so, the method 400 avoids the pattern collapse that often occurs when a relatively thick photoresist film layer (e.g., a photoresist film having a film thickness >20 nm) is developed in a single wet or dry development step, and avoids damaging the photoresist film stack when transferring the photoresist pattern to underlying target layer(s).

The method 400 shown in FIG. 4 differs from the method 100 explicitly shown in FIG. 1 by including an EUV enhancement layer, first photoresist layer, barrier layer and second photoresist layer within the multilayer photoresist film stack. When an EUV enhancement layer and barrier layer are included along with the photoresist layers, the combined thickness of the multilayer photoresist film stack ranges between 2 nm and 35 nm. As noted above, the EUV enhancement layer increases exposure of the first photoresist layer to the EUV radiation during the single exposure step, thus allowing the EUV dose to be reduced. The barrier layer improves adhesion for the second photoresist layer and provides an etch stop during the first development process, thus further improving development selectivity between the first and second photoresist layers.

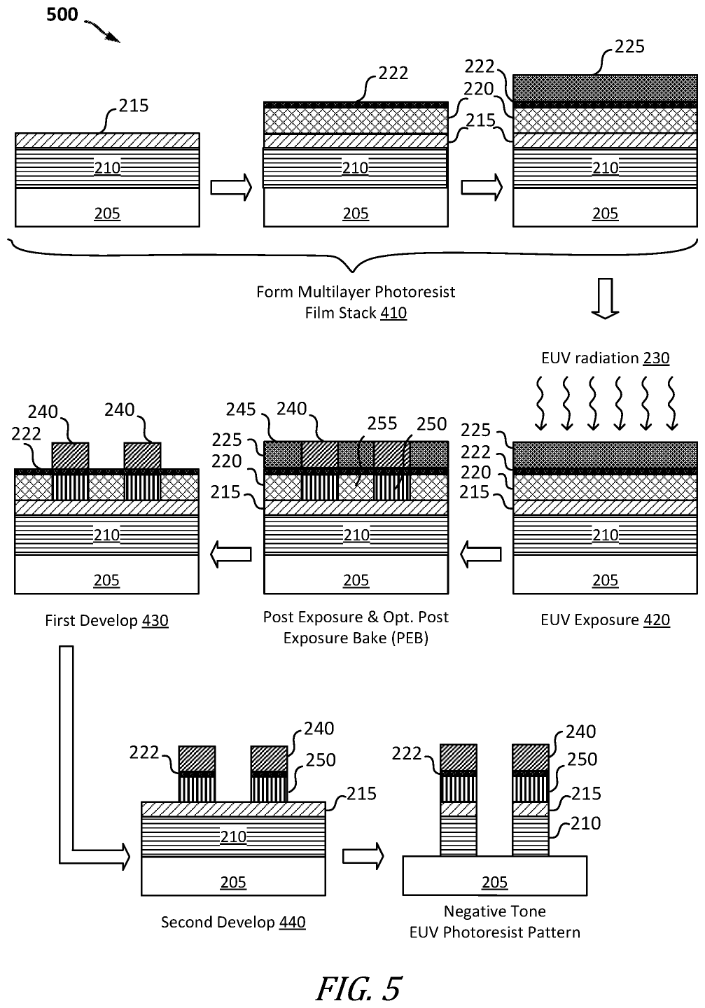

FIG. 5 illustrates one example of a process flow 500 that utilizes the method 400 shown in FIG. 4 to form an EUV photoresist pattern on a semiconductor substrate in accordance with a third embodiment of the present disclosure. Like the method 400 described above, the process flow 500 begins by forming a multilayer photoresist film stack on a surface of a semiconductor substrate 205 (in step 410). In the process flow 500 shown in FIG. 5, the multilayer photoresist film stack is formed in step 410 by: (a) depositing an EUV enhancement layer 215 on at least one underlayer 210 provided on the surface of the semiconductor substrate 205; (b) depositing a first photoresist layer 220 on the EUV enhancement layer 215; (c) depositing a barrier layer 222 on the first photoresist layer 220; and (d) depositing a second photoresist layer 225 on the barrier layer 222. The EUV enhancement layer 215, the first photoresist layer 220, the barrier layer 222 and the second photoresist layer 225 may comprise various materials and layer thicknesses, as described above in reference to FIGS. 1-3.

Like the process flows 200/300 shown in FIGS. 2-3, the process flow 500 uses EUV lithography to pattern the multilayer photoresist film stack and form an EUV photoresist pattern on the semiconductor substrate 205. As shown in FIG. 5, the EUV lithography process exposes the semiconductor substrate 205 containing the multilayer photoresist film stack to EUV radiation 230 (for example, at a wavelength of 13.5 nm) in a single EUV exposure step 420 convert regions 250 of the first photoresist layer 220 and regions 240 of the second photoresist layer 225 exposed to the EUV radiation 230 to reacted regions, while regions 255 of the first photoresist layer 220 and regions 245 of the second photoresist layer 225 not exposed to the EUV radiation 230 remain unchanged as unreacted regions. As noted above, the process conditions utilized during the EUV exposure step (e.g., EUV dose and exposure time) may be selected to ensure that the regions of the first photoresist layer and the regions of the second photoresist layer not covered by an overlying photomask are adequately exposed to EUV radiation to convert the exposed regions 240/250 into reacted photoresist in a single exposure step. Examples of process conditions used during the EUV exposure step 420 are discussed above in reference to FIG. 2.

After completing the EUV exposure step 420 (and optional PEB step), a first development process is performed (in step 430) to remove the reacted regions (in case of a positive tone resist) or the unreacted regions (in case of a negative tone resist) of the second photoresist layer 225 and form a pattern in the second photoresist layer 225. The first development process may be a wet development process or a dry development process, depending on the resist material used in the second photoresist layer 225. In one example, a portion of the second photoresist layer 225 may be removed by treating the substrate with a develop solution (e.g., PGMEA, TMAH, etc.) to dissolve the reacted regions 240 (in case of a positive tone resist) or unreacted regions 245 (in case of a negative tone resist) of the second photoresist layer 225 when the second photoresist layer 225 includes a CAR material. Alternately, a dry development process may be used to remove the reacted regions 240 or the unreacted regions 245 of the second photoresist layer 225 when the second photoresist layer 225 includes a MOR material.

Regardless of whether a wet or dry process is used, the first development process performed in step 430 selectively develops the second photoresist layer 225 by removing select portions of the second photoresist layer 225 without reacting with or removing any portion of the first photoresist layer 220 underlying the second photoresist layer 225. The barrier layer 222 improves development selectivity between the second photoresist layer 225 and the first photoresist layer 220 by providing etch stop for the first development process. In the process flow 500, the first development process performed in step 430 selectively develops the second photoresist layer 225 by removing the unreacted regions 245 of the second photoresist layer 225 to form a negative tone resist pattern in the second photoresist layer 225. However, one skilled in the art would readily understand how the first development process could be modified to remove reacted regions 240 of the second photoresist layer 225 to form a positive tone resist pattern in the second photoresist layer 225.

After selectively developing the second photoresist layer 225, a second development process is performed (in step 440) to remove the reacted regions (in case of a positive tone resist) or the unreacted regions (in case of a negative tone resist) of the first photoresist layer 220 and form a pattern in the first photoresist layer 220. The second development process may be a wet development process or a dry development process, depending on the resist material used in the first photoresist layer 220. In one example, a dry development process may be used to remove the reacted regions 250 (in case of a positive tone resist) or unreacted regions 255 (in case of a negative tone resist) of the first photoresist layer 220 when the first photoresist layer 220 includes a MOR material. As noted above, exposed portions of the barrier layer 222 may be removed during the first development process (in step 430) or the second development process (in step 440), as shown in FIG. 5.

Like the first development process, the second development process performed in step 440 selectively develops the first photoresist layer 220 by removing select portions of the first photoresist layer 220 without reacting with or removing any portion of the second photoresist layer 225 overlying the first photoresist layer 220. In the process flow 500, the second development process performed in step 440 selectively develops the first photoresist layer 220 by removing the unreacted regions 255 of the first photoresist layer 220 to form a negative tone resist pattern in the first photoresist layer 220. However, one skilled in the art would readily understand how the second development process could be modified to remove the reacted regions 250 of the first photoresist layer 220 to form a positive tone resist pattern in the first photoresist layer 220. After selectively developing the first photoresist layer 220, additional processing step(s) may be performed to transfer the resist pattern to the at least one underlayer 210, thereby forming an EUV photoresist pattern on the semiconductor substrate 205. The semiconductor substrate 205 may generally include one or more target layers for pattern transfer.

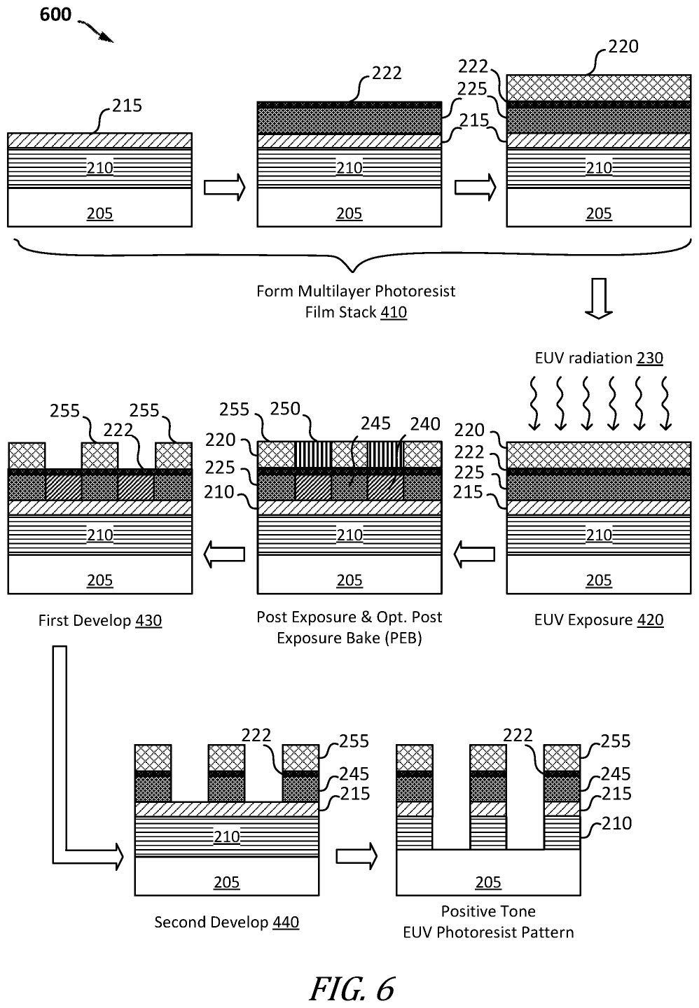

FIG. 6 illustrates another example of a process flow 600 that utilizes the method 400 shown in FIG. 4 to form an EUV photoresist pattern on a semiconductor substrate, according to a fourth embodiment of the present disclosure. Many of the process flow 600 steps shown in FIG. 6 are identical to the process flow 500 steps shown in FIG. 5, and thus, will not be repeated herein for the purpose of brevity. The process flow 600 differs from the process flow 500 by depositing the second photoresist layer 225 on the EUV enhancement layer 215 and depositing the first photoresist layer 220 on the barrier layer 222 in step 410. During the development steps 430 and 440, the process flow 600 selectively develops the first and second photoresist layers by removing the reacted regions 250 of the first photoresist layer 220, and subsequently removing the reacted regions 240 of the second photoresist layer 225 to form a positive tone EUV photoresist pattern on the semiconductor substrate 205.

In the process flow 600, the first photoresist layer 220 and the second photoresist layer 225 comprise different types of photosensitive materials. In one example, the second photoresist layer 225 deposited on the EUV enhancement layer 215 is a negative photoresist (e.g., a negative tone MOR) and the first photoresist layer 220 deposited on the barrier layer 222 is a positive photoresist (e.g., a positive tone CAR). In one embodiment, a wet development process may be used in step 430 to selectively remove the reacted regions 250 of the first photoresist layer 220 by treating the semiconductor substrate 205 with a develop solution (e.g., PGMEA, TMAH, etc.), which dissolves the reacted regions 250, while leaving the unreacted regions 255, of the first photoresist layer 220. Thereafter, a dry development process may be used in step 440 to selectively remove the reacted regions 240 of the second photoresist layer 225 by exposing the semiconductor substrate 205 to a gas-phase developer (e.g., a halogen containing gas), which etches the reacted regions 240, while leaving the unreacted regions 245, of the second photoresist layer 225.

In other embodiments, wet development processes may be used in steps 430 and 440, as long as different developing solutions are used to selectively develop the photoresist layers. In one example, a PGMEA solution may be used in step 430 to selectively remove the reacted regions 250 of the first photoresist layer 220 when the first photoresist layer 220 comprises a positive tone CAR, and a TMAH solution may be used in step 440 to selectively remove the reacted regions 240 of the second photoresist layer 225 when the second photoresist layer 225 comprises a negative tone MOR. One skilled in the art would readily understand how other developing solutions may be used to selectively develop the first photoresist layer 220 and the second photoresist layer 225.

Improved process flows and methods for forming an EUV photoresist pattern for use in EUV photolithographic processes are described in various embodiments. The process flows and methods shown in FIGS. 1-6 and disclosed above improve upon conventional methods of forming EUV-active photoresists by providing a multilayer photoresist film stack that combines a plurality of relatively thin, yet different, photoresist film layers. By combining different photoresist layers within a multilayer photoresist film stack, and using two different development steps to selectively develop the different photoresist layers, the process flows and methods disclosed herein increase resist thickness and improve development selectivity. In doing so, the improved process flows and methods disclosed herein avoid the photoresist damage and photoresist pattern collapse that often occurs during conventional EUV lithography processes, while meeting resolution (LER, LWR) and sensitivity (dose) requirements for EUV lithography. In some embodiments, use of the multilayer photoresist film stack described herein may enable on or more of the underlayers (e.g., the UL and/or ML underlayer) to be removed, thus reducing the overall thickness of the stack.

The techniques described herein allow for flexibility in material selection for the layers included within the multilayer photoresist film stack. As noted above, the photoresist layers may include a wide variety of EUV-active photoresist materials including, but not limited to, chemically amplified resist (CAR) materials and metal oxide resist (MOR) materials. In some embodiments, one of the photoresist layers (e.g., the top or bottom photoresist layer) within the multilayer photoresist film stack may comprise a CAR material, while the other photoresist layer (e.g., the bottom or top photoresist layer) comprises a MOR material. Alternatively, the photoresist layers included within the multilayer photoresist film stack may each comprise MOR materials having different organometallic oxides. The use of different photoresist materials enables the process flows and methods disclosed herein to selectively develop the photoresist layers in separate development steps. This selective development, along with the barrier layer optionally included within the multilayer photoresist film stack, increases selectivity and mitigates pattern collapse.

As illustrated in the process flows shown above, the techniques described herein can be used to form negative tone or positive tone photoresist patterns on a semiconductor substrate. In some embodiments, the top and bottom photoresist layers may each comprise a negative photoresist, and the EUV exposure and development steps may be performed to form a negative tone EUV photoresist pattern on the substrate, as shown in FIGS. 2, 3 and 5. In other embodiments, the bottom photoresist layer may comprise a negative photoresist and the top photoresist layer may comprise a positive photoresist, and the EUV exposure and development steps may be performed to form a positive tone EUV photoresist pattern on the substrate, as shown in FIG. 6. In some embodiments, a positive tone EUV photoresist pattern may also be formed using a positive photoresist for the top photoresist layer and a negative photoresist for the bottom photoresist layer.

The term “substrate” as used herein means and includes a base material or construction upon which materials are formed. It will be appreciated that the substrate may include a single material, a plurality of layers of different materials, a layer or layers having regions of different materials or different structures in them, etc. These materials may include semiconductors, insulators, conductors, or combinations thereof. For example, the substrate may be a semiconductor substrate, a base semiconductor layer on a supporting structure, a metal electrode or a semiconductor substrate having one or more layers, structures or regions formed thereon. The substrate may be a conventional silicon substrate or other bulk substrate comprising a layer of semi-conductive material. As used herein, the term “bulk substrate” means and includes not only silicon wafers, but also silicon-on-insulator (“SOI”) substrates, such as silicon-on-sapphire (“SOS”) substrates and silicon-on-glass (“SOG”) substrates, epitaxial layers of silicon on a base semiconductor foundation, and other semiconductor or optoelectronic materials, such as silicon-germanium, germanium, gallium arsenide, gallium nitride, and indium phosphide. The substrate may be doped or undoped.

The substrate may also include any material portion or structure of a device, particularly a semiconductor or other electronics device, and may, for example, be a base substrate structure, such as a semiconductor substrate or a layer on or overlying a base substrate structure. Thus, the term “substrate” is not intended to be limited to any particular base structure, underlying layer or overlying layer, patterned layer or unpatterned layer, but rather, is contemplated to include any such layer or base structure, and any combination of layers and/or base structures.

It is noted that reference throughout this specification to “one embodiment” or “an embodiment” means that a particular feature, structure, material, or characteristic described in connection with the embodiment is included in at least one embodiment of the invention, but do not denote that they are present in every embodiment. Thus, the appearances of the phrases “in one embodiment” or “in an embodiment” in various places throughout this specification are not necessarily referring to the same embodiment of the invention. Furthermore, the particular features, structures, materials, or characteristics may be combined in any suitable manner in one or more embodiments. Various additional layers and/or structures may be included and/or described features may be omitted in other embodiments.

One skilled in the relevant art will recognize that the various embodiments may be practiced without one or more of the specific details, or with other replacement and/or additional methods, materials, or components. In other instances, well-known structures, materials, or operations are not shown or described in detail to avoid obscuring aspects of various embodiments of the invention. Similarly, for purposes of explanation, specific numbers, materials, and configurations are set forth in order to provide a thorough understanding of the invention. Nevertheless, the invention may be practiced without specific details. Furthermore, it is understood that the various embodiments shown in the figures are illustrative representations and are not necessarily drawn to scale.

Further modifications and alternative embodiments of the methods described herein will be apparent to those skilled in the art in view of this description. It will be recognized, therefore, that the described methods are not limited by these example arrangements. It is to be understood that the forms of the methods herein shown and described are to be taken as example embodiments. Various changes may be made in the implementations. Thus, although the inventions are described herein with reference to specific embodiments, various modifications and changes can be made without departing from the scope of the present inventions. Accordingly, the specification and figures are to be regarded in an illustrative rather than a restrictive sense, and such modifications are intended to be included within the scope of the present inventions. Further, any benefits, advantages, or solutions to problems that are described herein with regard to specific embodiments are not intended to be construed as a critical, required, or essential feature or element of any or all the claims.

What is claimed is:

1. A method of processing a semiconductor substrate, the method comprising:
forming a multilayer photoresist film stack on a surface of the semiconductor substrate, the multilayer photoresist film stack comprising a first photoresist layer and a second photoresist layer formed above the first photoresist layer, the first photoresist layer comprising a metal oxide resist material, and the second photoresist layer comprising a resist material that differs from the metal oxide resist material used in the first photoresist layer;
exposing the multilayer photoresist film stack to extreme ultra-violet (EUV) radiation in a single exposure step to: (a) convert regions of the first photoresist layer exposed to the EUV radiation to reacted regions, while regions of the first photoresist layer not exposed to the EUV radiation remain unchanged as unreacted regions, and (b) convert regions of the second photoresist layer exposed to the EUV radiation to reacted regions, while regions of the second photoresist layer not exposed to the EUV radiation remain unchanged as unreacted regions;
exposing the multilayer photoresist film stack to a first development process to selectively develop the second photoresist layer by removing the reacted regions or the unreacted regions of the second photoresist layer to form a pattern in the second photoresist layer; and
exposing the multilayer photoresist film stack to a second development process to selectively develop the first photoresist layer by removing the reacted regions or the unreacted regions of the first photoresist layer to form a pattern in the first photoresist layer.

2. The method of claim 1, wherein the metal oxide resist material used in the first photoresist layer comprises an organometallic oxide containing a central metal atom of tin (Sn), zirconium (Zr), indium (In), antimony (Sb), bismuth (Bi), zinc (Zn), hafnium (Hf), aluminum (AI), or combinations thereof.

3. The method of claim 2, wherein said forming the multilayer photoresist film stack comprises:
forming an EUV enhancement layer on at least one underlayer provided on the surface of the semiconductor substrate, the EUV enhancement layer comprising a metal or non-metal material that generates and emits secondary electrons when exposed to the EUV radiation; and
forming the first photoresist layer on the EUV enhancement layer;
wherein the EUV enhancement layer increases exposure of the first photoresist layer to the EUV radiation during the single exposure step.

4. The method of claim 2, wherein said exposing the multilayer photoresist film stack to the second development process comprises:
exposing the multilayer photoresist film stack to a dry development process to remove the reacted regions or the unreacted regions of the first photoresist layer and form the pattern in the first photoresist layer.

5. The method of claim 4, wherein said exposing the multilayer photoresist film stack to the dry development process comprises:
exposing the surface of the semiconductor substrate to one or more process gases, which react with exposed surfaces of the first photoresist layer to remove the reacted regions or the unreacted regions of the first photoresist layer;
wherein the one or more process gases comprise hydrogen (H₂), ammonia (NH₃), a halogen containing gas or combinations thereof.

6. The method of claim 2, wherein the second photoresist layer comprises a chemically amplified resist (CAR) material, and wherein said exposing the multilayer photoresist film stack to the first development process comprises:
exposing the multilayer photoresist film stack to a wet development process to remove the reacted regions or the unreacted regions of the second photoresist layer and form the pattern in the second photoresist layer.

7. The method of claim 6, wherein exposing the multilayer photoresist film stack to the wet development process comprises:
exposing the surface of the semiconductor substrate to a develop solution to dissolve the reacted regions or the unreacted regions of the second photoresist layer;
wherein the develop solution comprises propylene glycol methyl ether acetate (PGMEA), tetramethylammonium hydroxide (TMAH), normal butyl alcohol (NBA), 2-heptanone or an organic solvent with an acid additive.

8. The method of claim 6, wherein said forming the multilayer photoresist film stack comprises:
forming a barrier layer on the first photoresist layer, the barrier layer comprising a hydrophilic material; and
forming the second photoresist layer on the barrier layer;
wherein the barrier layer improves adhesion for the second photoresist layer and provides an etch stop during the first development process.

9. The method of claim 2, wherein the second photoresist layer comprises a metal oxide resist material that differs from the metal oxide resist material used in the first photoresist layer, and wherein said exposing the multilayer photoresist film stack to the first development process comprises:
exposing the multilayer photoresist film stack to a dry development process to remove the reacted regions or the unreacted regions of the second photoresist layer and form the pattern in the second photoresist layer.

10. The method of claim 9, wherein the metal oxide resist material used in the second photoresist layer comprises an organometallic oxide containing a central metal atom of tin (Sn), zirconium (Zr), indium (In), antimony (Sb), bismuth (Bi), zinc (Zn), hafnium (Hf), or aluminum (Al), or combinations thereof, and wherein the organometallic oxide included within the second photoresist layer differs from the organometallic oxide included within the first photoresist layer.

11. The method of claim 9, wherein exposing the multilayer photoresist film stack to the dry development process comprises:
exposing the surface of the semiconductor substrate to one or more process gases, which react with exposed surfaces of the second photoresist layer to remove the reacted regions or the unreacted regions of the second photoresist layer;
wherein the one or more process gases comprise hydrogen (H₂), ammonia (NH₃), a halogen containing gas or combinations thereof.

12. The method of claim 1, wherein said forming the multilayer photoresist film stack comprises:
forming an EUV enhancement layer on at least one underlayer provided on the surface of the semiconductor substrate, wherein the EUV enhancement layer comprises a metal or non-metal material that generates and emits secondary electrons when exposed to the EUV radiation, and wherein the EUV enhancement layer has a thickness ranging between 0.5 nm and 5 nm;
forming the first photoresist layer on the EUV enhancement layer, wherein the metal oxide resist material used in the first photoresist layer comprises a first organometallic oxide and has a thickness ranging between 1 nm and 15 nm;
forming a barrier layer on the first photoresist layer, wherein the barrier layer comprises a hydrophilic material and has a thickness ranging between about one monolayer to less than 2 nm; and
forming the second photoresist layer on the barrier layer, wherein the second photoresist layer comprises: (a) a chemically amplified resist (CAR) material, or (b) a metal oxide resist material that differs from the metal oxide resist material used in the first photoresist layer, and has a thickness ranging between 1 nm and 15 nm.

13. The method of claim 12, wherein said forming the multilayer photoresist film stack comprises:
forming the EUV enhancement layer, the first photoresist layer, the barrier layer and the second photoresist layer such that a combined thickness of the multilayer photoresist film stack ranges between 2 nm and 35 nm.

14. A method of processing a semiconductor substrate, the method comprising:
forming a multilayer photoresist film stack on a surface of the semiconductor substrate by:
(a) depositing an extreme ultra-violet (EUV) enhancement layer on at least one underlayer provided on the surface of the semiconductor substrate;
(b) depositing a first photoresist layer on the EUV enhancement layer, the first photoresist layer comprising a metal oxide resist material;
(c) depositing a barrier layer on the first photoresist layer; and
(d) depositing a second photoresist layer on the barrier layer, the second photoresist layer comprising a resist material that differs from the metal oxide resist material used in the first photoresist layer;
exposing the multilayer photoresist film stack to EUV radiation in a single exposure step to convert regions of the first photoresist layer and regions of the second photoresist layer exposed to the EUV radiation to reacted regions, while regions of the first photoresist layer and regions of the second photoresist layer not exposed to the EUV radiation remain unchanged as unreacted regions;
exposing the multilayer photoresist film stack to a first development process to selectively develop the second photoresist layer by removing the reacted regions or the unreacted regions of the second photoresist layer to form a pattern in the second photoresist layer; and
exposing the multilayer photoresist film stack to a second development process to selectively develop the first photoresist layer by removing the reacted regions or the unreacted regions of the first photoresist layer to form a pattern in the first photoresist layer.

15. The method of claim 14, wherein a combined thickness of the multilayer photoresist film stack ranges between 2 nm and 35 nm, and wherein said forming the multilayer photoresist film stack, said exposing the multilayer photoresist film stack to the first development process and said exposing the multilayer photoresist film stack to the second development process forms a pattern in the second photoresist layer and in the first photoresist layer that avoids pattern collapse.

16. The method of claim 14, wherein said depositing the first photoresist layer comprises:
depositing the metal oxide resist material on the EUV enhancement layer, the metal oxide resist material comprising an organometallic oxide and having a thickness ranging between 1 nm and 15 nm.

17. The method of claim 16, wherein said exposing the multilayer photoresist film stack to the second development process comprises:
exposing the multilayer photoresist film stack to a dry development process to remove the reacted regions or the unreacted regions of the first photoresist layer and form the pattern in the first photoresist layer.

18. The method of claim 14, wherein said depositing the second photoresist layer comprises:
depositing a chemically amplified resist (CAR) material on the barrier layer, the CAR material having a thickness ranging between 1 nm and 15 nm.

19. The method of claim 18, wherein said exposing the multilayer photoresist film stack to the first development process comprises:
exposing the multilayer photoresist film stack to a wet development process to remove the reacted regions or the unreacted regions of the second photoresist layer and form the pattern in the second photoresist layer.

20. The method of claim 14, wherein said depositing the second photoresist layer comprises:
depositing a metal oxide resist material, which differs from the metal oxide resist material used in the first photoresist layer, on the barrier layer, the metal oxide resist material used within the second photoresist layer comprising an organometallic oxide, which differs from an organometallic oxide included within the first photoresist layer, and having a thickness ranging between 1 nm and 15 nm.

21. The method of claim 20, wherein said exposing the multilayer photoresist film stack to the first development process comprises:
exposing the multilayer photoresist film stack to a dry development process to remove the reacted regions or the unreacted regions of the second photoresist layer and form the pattern in the second photoresist layer.

22. The method of claim 14, wherein the EUV enhancement layer, the first photoresist layer and the barrier layer are deposited in situ within the same process chamber.

23. The method of claim 14, wherein the first photoresist layer and the second photoresist each comprise a negative photoresist, and wherein said exposing the multilayer photoresist film stack to the EUV radiation, said exposing the multilayer photoresist film stack to the first development process and said exposing the multilayer photoresist film stack to the second development process forms a negative tone EUV photoresist pattern.

24. The method of claim 14, wherein the first photoresist layer comprises a negative photoresist and the second photoresist comprises a positive photoresist, and wherein said exposing the multilayer photoresist film stack to the EUV radiation, said exposing the multilayer photoresist film stack to the first development process and said exposing the multilayer photoresist film stack to the second development process forms a positive tone EUV photoresist pattern.
